(19) United States
(12) Patent Application Publication
(10) Pub. No.: US 2024/0365646 A1
(43) Pub. Date: Oct. 31, 2024

(54) DISPLAY DEVICE AND METHOD OF MANUFACTURING DISPLAY DEVICE

(71) Applicant: SAMSUNG DISPLAY CO., LTD., YONGIN-SI (KR)

(72) Inventors: Cheon Myeong LEE, Yongin-si (KR); Soo Min BAEK, Yongin-si (KR); Ju Youn SON, Yongin-si (KR); Sang Ho KIM, Yongin-si (KR); Ji Won LEE, Yongin-si (KR); Baek Hyeon LIM, Yongin-si (KR); Ju Hwa HA, Yongin-si (KR)

(21) Appl. No.: 18/432,135

(22) Filed: Feb. 5, 2024

(30) Foreign Application Priority Data
Apr. 26, 2023 (KR) 10-2023-0054989

(51) Int. Cl. H10K 59/80; H10K 59/12; H10K 77/10; H10K 102/00

(52) U.S. Cl. CPC H10K 59/878; H10K 59/1201; H10K 77/111; H10K 2102/311; H10K 2102/351

(57) ABSTRACT

A display device includes: a base layer; a pixel circuit layer disposed on the base layer, wherein the pixel circuit layer includes a pixel circuit; a light emitting element layer disposed on the pixel circuit layer, wherein the light emitting element layer includes a light emitting element electrically connected to the pixel circuit; and a reflective structure layer disposed on the light emitting element layer, wherein the reflective structure layer includes: a first intermediate layer disposed on the light emitting element; a first reflective layer disposed on the first intermediate layer; a second intermediate layer disposed on the first reflective layer; and a second reflective layer disposed on the first reflective layer while being spaced apart from the first reflective layer, wherein the first reflective layer includes a first curved surface, and wherein the second reflective layer includes a second curved surface which faces the first curved surface.

### CROSS-REFERENCE TO RELATED APPLICATION

The present application claims priority under 35 U.S.C. § 119(a) to Korean patent application No. 10-2023-0054989 filed on Apr. 26, 2023 in the Korean Intellectual Property Office, the disclosure of which is incorporated by reference herein in its entirety.

### TECHNICAL FIELD

The present invention relates to a display device and a method of manufacturing a display device.

### DISCUSSION OF THE RELATED ART

Generally, a display device may include a light emitting layer capable of emitting light. Light emitted from the light emitting layer may be emitted to the outside of the display device while passing through one or more components of the display device.

When a portion of the light, which is emitted from the light emitting layer, is not emitted to the outside by internal components of the display device, the light emission efficiency of the display device may be reduced.

Accordingly, the display device including a light emitting layer capable of emitting light has been under development.

### SUMMARY

According to an embodiment of the present invention, a display device includes: a base layer; a pixel circuit layer disposed on the base layer, wherein the pixel circuit layer includes a pixel circuit; a light emitting element layer disposed on the pixel circuit layer, wherein the light emitting element layer includes a light emitting element electrically connected to the pixel circuit; and a reflective structure layer disposed on the light emitting element layer, wherein the reflective structure layer includes: a first intermediate layer disposed on the light emitting element; a first reflective layer disposed on the first intermediate layer; a second intermediate layer disposed on the first reflective layer; and a second reflective layer disposed on the first reflective layer while being spaced apart from the first reflective layer, wherein the first reflective layer includes a first curved surface, and wherein the second reflective layer includes a second curved surface which faces the first curved surface and is spaced apart from the first curved surface.

In an embodiment of the present invention, the first curved surface and the second curved surface protrude in a direction in which the light emitting element is disposed.

In an embodiment of the present invention, the first curved surface and the second curved surface are bent in a same direction as each other.

In an embodiment of the present invention, the first curved surface is a paraboloid, and the second curved surface is a hyperboloid.

In an embodiment of the present invention, the first reflective layer and the second reflective layer have a same radius of curvature radius as each other.

In an embodiment of the present invention, the first reflective layer and the second reflective layer have a different radius of curvature from each other.

In an embodiment of the present invention, the light emitting element includes: a first electrode; a light emitting layer disposed on the first electrode; and a second electrode disposed on the light emitting layer, wherein the first reflective layer includes an opening, wherein the second reflective layer does not include an opening, and wherein the opening of the first reflective layer, the light emitting layer, and the second reflective layer overlap with each other.

In an embodiment of the present invention, an area in which the second reflective layer is disposed entirely overlaps with an area in which the light emitting layer is disposed.

In an embodiment of the present invention, a center of the first reflective layer and a center of the second reflective layer correspond to each other.

In an embodiment of the present invention, a center of the first reflective layer and a center of the second reflective layer are misaligned with each other.

In an embodiment of the present invention, the first reflective layer has a single-layer structure, which includes at least one of aluminum (Al) or magnesium (Mg), or a multi-layer structure in which titanium oxide (TixOy) and silicon oxide (SixOy) are stacked on each other, and the second reflective layer has a single-layer structure, which includes at least one of aluminum (Al) and magnesium (Mg), or a multi-layer structure in which titanium oxide (TixOy) and silicon oxide (SixOy) are stacked on each other.

According to an embodiment of the present invention, a display device includes: a base layer; a pixel circuit layer disposed on the base layer, wherein the pixel circuit layer includes a pixel circuit; a light emitting element layer disposed on the pixel circuit layer, wherein the light emitting element layer includes a light emitting element electrically connected to the pixel circuit; and a reflective structure layer disposed on the light emitting element layer, wherein the light emitting element layer includes: a first electrode; a light emitting layer disposed on the first electrode; and a second electrode disposed on the light emitting layer, wherein the reflective structure layer includes: a first intermediate layer disposed on the second electrode; a first reflective layer disposed on the first intermediate layer, wherein the first reflective layer includes an opening; a second intermediate layer disposed on the first reflective layer; and a second reflective layer disposed on the second intermediate layer, wherein the first reflective layer has a first curved surface, and the second reflective layer has a second curved surface, and wherein an area in which the opening of the first reflective layer is disposed overlaps with an area in which the light emitting layer is disposed.

In an embodiment of the present invention, each of the first curved surface and the second curved surface includes a surface inclined with respect to a top surface of the first intermediate layer.

In an embodiment of the present invention, the first reflective layer and the second reflective layer have a Cassegrain type arrangement form.

In an embodiment of the present invention, the light emitting layer emits light, and wherein at least a portion of the light passes through the opening, at least a portion of the light is reflected from the second reflective layer, and at least a portion of the light is reflected from the first reflective layer.

In an embodiment of the present invention, the light is emitted to an area overlapping with the first reflective layer.

According to an embodiment of the present invention, a method of manufacturing a display device includes: patterning a pixel circuit layer on a base layer; patterning a light emitting element layer on the pixel circuit layer; and patterning a reflective structure layer on the light emitting element layer, wherein the patterning of the reflective structure layer on the light emitting element layer includes: forming a first intermediate layer on the light emitting element layer; patterning a first reflective layer on the first intermediate layer; forming a second intermediate layer on the first reflective layer; and patterning a second reflective layer on the second intermediate layer, and wherein the first reflective layer includes a first curved surface, and the second reflective layer includes a second curved surface.

In an embodiment of the present invention, the forming of the first intermediate layer on the light emitting element layer includes: depositing the first intermediate layer on the light emitting element layer; applying a first photoresist, which includes a first area, on the first intermediate layer; and etching the first photoresist, which includes the first area, and a portion of the first intermediate layer that overlaps with the first area, and wherein the first intermediate layer is etched to form a curved surface.

In an embodiment of the present invention, the forming of the second intermediate layer on the first reflective layer includes: depositing the second intermediate layer on the first reflective layer; applying a second photoresist, which includes a second area, on the second intermediate layer; and etching the second photoresist, which includes the second area, and a portion of the second intermediate layer that overlaps with the second area, and wherein the second intermediate layer is etched to form a curved surface.

In an embodiment of the present invention, the first reflective layer includes at least one of aluminum (Al), magnesium (Mg), titanium oxide (TixOy), or silicon oxide (SixOy), and the second reflective layer includes at least one of aluminum (Al), magnesium (Mg), titanium oxide (TixOy), or silicon oxide (SixOy).

### BRIEF DESCRIPTION OF THE DRAWINGS

FIG. 1 is a schematic plan view illustrating a display device in accordance with an embodiment of the present invention.

FIGS. 2A, 2B and 2C are schematic plan views illustrating a pixel shown in FIG. 1 according to embodiments of the present invention.

FIG. 3 is a schematic sectional view of a display device in accordance with an embodiment of the present invention.

FIG. 4 is a schematic sectional view illustrating a reflective structure layer and a light emitting element layer, taken along line A-A′ shown in FIG. 2A.

FIG. 5 is a schematic plan view of a display device shown in FIG. 4 in accordance with an embodiment of the present invention.

FIGS. 6 and 7 are schematic views illustrating emission directions of light, which is determined by a reflective structure layer in accordance with an embodiment of the present invention.

FIG. 8 is a plan view of a display device shown in FIG. 7.

FIG. 9 is a flowchart illustrating a method of manufacturing a display device in accordance with an embodiment of the present invention.

FIGS. 10, 11, 12, 13, 14, 15 and 16 are process sectional views of the display device illustrating various steps of the method of manufacturing the display device according to an embodiment of the present invention.

FIGS. 17 and 18 are schematic views illustrating examples of an electronic device including the display device shown in FIG. 1 according to an embodiment of the present invention.

### DETAILED DESCRIPTION OF THE EMBODIMENTS

Hereinafter, various embodiments of the present invention will be described in detail with reference to the accompanying drawings. The present invention may be embodied in various different forms and is not limited to the embodiments described herein.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings and spirit of the present invention. As used herein, the singular forms are intended to include the plural forms as well, unless the context clearly indicates otherwise.

Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Hereinafter, a display device and a method of manufacturing a display device in accordance with an embodiment of the present invention will be described with reference to the accompanying drawings.

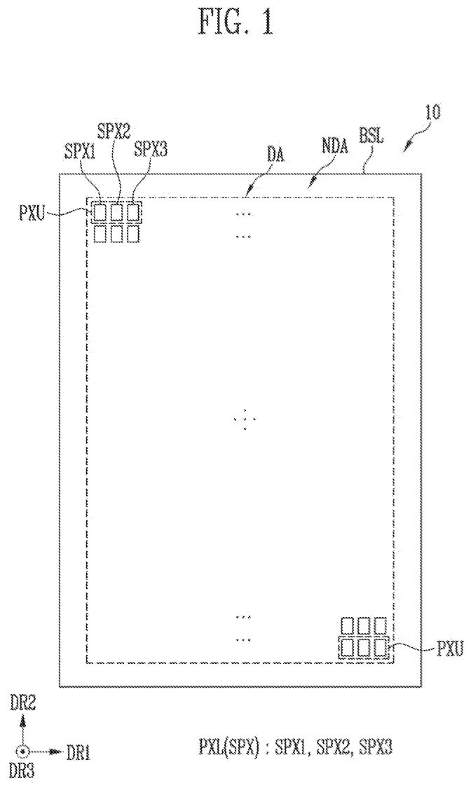

FIG. 1 is a schematic plan view illustrating a display device in accordance with an embodiment of the present invention.

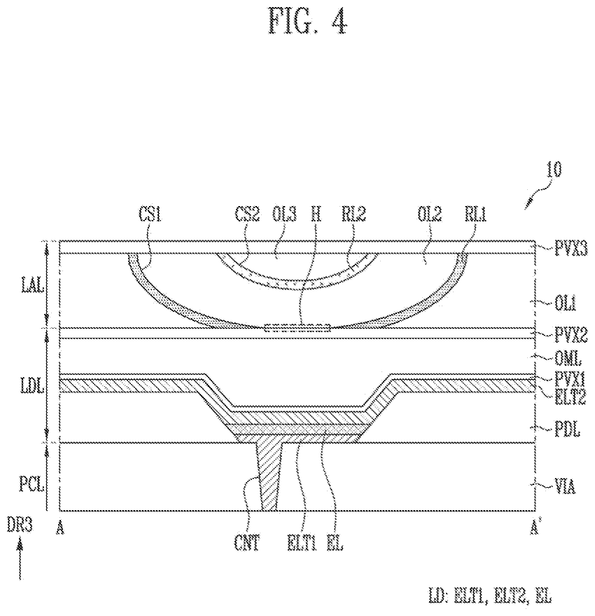

The display device 10 may be configured to emit light. The display device 10 may include a light emitting element LD (see FIG. 4). In some embodiments of the present invention, the display device 10 is a device which displays a moving image or a still image. The display device 10 may be used as a display screen of not only portable electronic devices such as a mobile phone, a smart phone, a tablet personal computer (PC), a smart watch, and a watch phone, but also various products such as a television, a notebook computer, a monitor, an advertisement board, Internet of things (IoT), and a micro display. However, the application field of the display device 10 is not limited to a specific example.

The display device 10 may have a rectangular shape having short sides in a first direction DR1 and long sides in a second direction DR2 intersecting the first direction DR1. However, the present invention is not limited thereto, and the display device 10 may have various shapes.

The display device 10 may include a display area DA and a non-display area NDA. The non-display area NDA may be an area except the display area DA. The non-display area NDA may at least partially surround at least a portion of the display area DA. For example, an image might not be displayed in the non-display area NDA.

The base layer BSL may form a base member of the display device 10. The base layer BSL may be a rigid or flexible substrate or film. For example, the base layer BSL may be a rigid substrate made of glass or tempered glass, a flexible substrate (or thin film) made of a plastic or metal material, or at least one insulating layer. In some embodiments of the present invention, the base layer BSL may include silicon (Si). The material and/or property of the base layer BSL is not particularly limited thereto. In an embodiment of the present invention, the base layer BSL may be substantially transparent. The term “substantially transparent” may mean that light can be transmitted with a predetermined transmittance or more. In an embodiment of the present invention, the base layer BSL may be translucent or opaque. In addition, the base layer BSL may include a reflective material in some embodiments of the present invention.

The display area DA may be an area in which pixels PXL are disposed. The non-display area NDA may be an area in which the pixels PXL are not disposed. The driving circuit, the lines, and the pads, which are connected to the pixels PXL of the display area DA, may be disposed in the non-display area NDA.

In some embodiments of the present invention, the pixels PXL (or sub-pixels SPX) may be arranged according to a stripe arrangement structure, a PENTILE™ arrangement structure, or the like. However, the present invention is not limited thereto.

In some embodiments of the present invention, the pixel PXL may include a light emitting element LD. The pixel PXL (or the sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may constitute one pixel unit PXU capable of emitting lights of various colors.

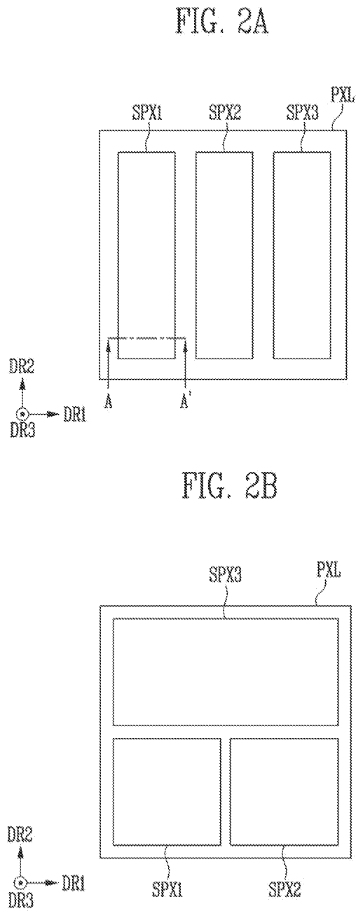

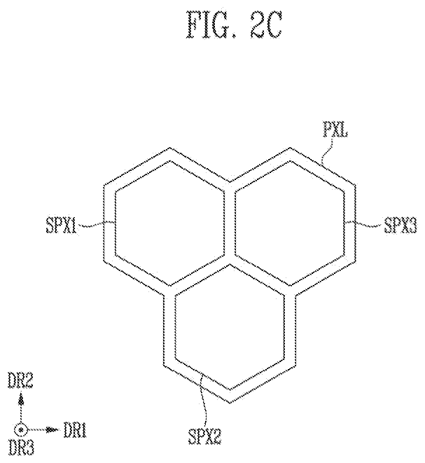

FIGS. 2A to 2C are schematic plan views illustrating a pixel shown in FIG. 1 according to embodiments of the present invention.

In FIGS. 2A to 2C, it is illustrated, as an example, that each of the pixels PXL includes three sub-pixels SPX1, SPX2, and SPX3. However, the embodiments of the present invention are not limited thereto.

Referring to 2A, the sub-pixels SPX may have, for example, a rectangular, square or rhombic planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 2A. In addition, the sub-pixels SPX may have a square or rhombic planar shape including sides having the same length in the first direction DR1 and the second direction DR2.

In an example, areas of the first to third sub-pixels SPX1 to SPX3 may be substantially the same as each other, but the present invention is not limited thereto. For example, at least one of the areas of the first to third sub-pixels SPX1 to SPX3 may be different from the area of another of the first to third sub-pixels SPX1 to SPX3. In addition, any two of the area of the first sub-pixel SPX1, the area of the second sub-pixel SPX2, and the area of the third sub-pixel SPX3 may be substantially the same as each other, and the other or remaining of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. In addition, the area of the first sub-pixel SPX1, the area of the second sub-pixel SPX2, and the area of the third sub-pixel SPX3 may be different from one another.

Referring to FIG. 2B, the first sub pixel SPX1 may be arranged with any one of the second sub-pixel SPX2 and the third sub-pixel SPX3 in the first direction DR1, and be arranged with the other or remaining of the second sub-pixel SPX2 and the third sub-pixel SPX3 in the second direction DR2. For example, the first sub-pixel SPX1 may be arranged with the second sub-pixel SPX2 in the first direction DR1, and be arranged with the third sub-pixel SPX3 in the second direction DR2.

In an example, the third sub-pixel SPX3 may be disposed in the second direction DR2 from the first sub-pixel SPX1 and the second sub-pixel SPX2. In an example, areas of the first and second sub-pixels SPX1 and SPX2 may be substantially the same as each other, and an area of the third sub-pixel SPX3 may be different from the areas of the first and second sub-pixels SPX1 and SPX2. For example, the area of the third sub-pixel SPX3 may be wider than the areas of the first and second sub-pixels SPX1 and SPX2.

Referring to FIG. 2C, each of the first sub-pixel SPX1, the second sub-pixel SPX2, and the third sub-pixel SPX3 may have a hexagonal or regular hexagonal planar shape. In an example, adjacent two surfaces among six surfaces of each of the first to third sub-pixels SPX1 to SPX3 may face one surfaces of adjacent sub-pixels.

The first sub-pixel SPX1 may emit first light, and the second sub-pixel SPX2 may emit second light. The third sub-pixel SPX3 may emit third light. The first light may be light in a red wavelength band, and the second light may be light in a green wavelength band. The third light may be light in a blue wavelength band.

Each of the first sub-pixel SPX1, the second sub-pixel SPX2, and the third sub-pixel SPX3 may include a light emitting element LD configured to emit light.

The light emitting element LD may be provided in various forms. For example, the light emitting element LD may be an inorganic light emitting element including an inorganic material. In some embodiments of the present invention, the light emitting element LD may be an Organic Light Emitting Diode (OLED). However, the present invention is not limited to a specific example.

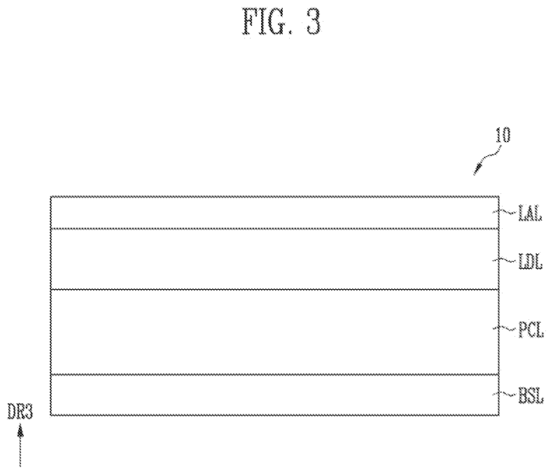

FIG. 3 is a schematic sectional view of a display device in accordance with an embodiment of the present invention.

Referring to FIG. 3, the display device 10 may include a base layer BSL, a pixel circuit layer PCL, a light emitting element layer LDL, and a reflective structure layer LAL.

The base layer BSL may form a base for allowing the pixel circuit layer PCL, the light emitting element layer LDL, and the reflective structure layer LAL to be disposed thereon.

The pixel circuit layer PCL may be a layer including a pixel circuit for driving a light emitting element LD. The pixel circuit layer PCL may include conductive layers for forming pixel circuits and insulating layers disposed between the conductive layers. In some embodiments of the present invention, the pixel circuit layer PCL may further include a via layer VIA (see FIG. 4) at an uppermost portion of the pixel circuit layer PCL. For example, the pixel circuit layer PCL may include conductive layers that may be connected to each other through vias. As another example, the pixel circuit layer PCL may include a plurality of transistors that are electrically connected to light emitting elements LD. However, the present invention is not necessarily limited thereto. The via layer VIA may be omitted in some embodiments of the present invention.

The pixel circuits may be electrically connected to light emitting elements LD to provide an electrical signal for the light emitting elements LD to emit light. For example, the pixel circuit layer PCL may include a thin film transistor.

The light emitting element layer LDL may be disposed on the pixel circuit layer PCL. The light emitting element layer LDL may include a light emitting element LD. In some embodiments of the present invention, the light emitting element layer LDL may be disposed between the pixel circuit layer PCL and the reflective structure layer LAL.

The reflective structure layer LAL may be disposed on the light emitting element layer LDL. The reflective structure layer LAL may be a layer for adjusting the direction of light emitted from a light emitting layer EL (see FIG. 4). The reflective structure layer LAL may be a layer for adjusting the light efficiency of the light emitting element LD. For example, the reflective structure layer LAL may include a layer which reflects light so as to increase light emission efficiency. The reflective structure layer LAL will be described in detail later with reference to FIG. 4.

FIG. 4 is a schematic sectional view illustrating a reflective structure layer and a light emitting element layer, taken along line A-A′ shown in FIG. 2A. Although it is illustrated that the line A-A′ shown in FIG. 2A cuts the first sub-pixel SPX1, a stacked structure of the display device 10 shown in FIG. 4 may be applied to the second sub-pixel SPX2 and the third sub-pixel SPX3.

For convenience of description, FIG. 4 illustrates a portion of the pixel circuit layer PCL, based on an embodiment in which the via layer VIA is disposed at an upper portion of the pixel circuit layer PCL. In some embodiments of the present invention, the via layer VIA may be a planarization layer, and include an organic material (e.g., polyimide resin, or the like).

Referring to FIG. 4, the light emitting element layer LDL may include a first electrode ELT1, a light emitting layer EL, a second electrode ELT2, a first protective layer PVX1, a second protective layer PVX2, a pixel defining layer PDL, and a planarization layer OML.

The first electrode ELT1 may be electrically connected to a pixel circuit formed in the pixel circuit layer PCL through a contact part CNT that is formed in the via layer VIA. The first electrode ELT1 may be an anode electrode of a light emitting element LD. However, the present invention is not limited thereto. The first electrode ELT1 may be a cathode electrode of the light emitting element LD.

The light emitting layer EL may be disposed on the first electrode ELT1. One surface of the light emitting layer EL may be electrically connected to the first electrode ELT1, and the other surface (e.g., opposing surface) of the light emitting layer EL may be electrically connected to the second electrode ELT2.

The light emitting layer EL may emit at least one of light in a red wavelength band, light in a green wavelength band, and light in a blue wavelength band. The light emitting layer EL may include an organic light emitting material.

For example, the light emitting layer EL may have a multi-layer thin film structure including a light generation layer. The light emitting layer EL may include, for example, a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. The light emitting layer EL may release light, based on an electrical signal provided from the first electrode ELT1 and the second electrode ELT2.

However, the present invention is not limited thereto. The light emitting layer EL may include an inorganic material. For example, the light emitting layer EL may include an inorganic light emitting material including gallium nitride (GaₓN_{y}), aluminum nitride (AlₓN_{y}), and the like.

The second electrode ELT2 may be disposed on the light emitting layer EL. The second electrode ELT2 may be the cathode electrode of the light emitting element LD. However, the present invention is not limited thereto, and the second electrode ELT2 may be the anode electrode of the light emitting element LD.

In some embodiments of the present invention, the first electrode ELT1 and the second electrode ELT2 may each include a conductive material. For example, the first electrode ELT1 may include a conductive material having reflexibility, and the second electrode ELT2 may include a transparent conductive material. However, the present invention is not necessarily limited thereto.

The pixel defining layer PDL may include an opening in which the light emitting layer EL is disposed. For example, the first electrode ELT1 may be disposed in the opening of the pixel defining layer PDL. The pixel defining layer PDL may be disposed on the via layer VIA, to define a position at which the light emitting layer EL is arranged. The pixel defining layer PDL may be disposed adjacent to the light emitting layer EL.

The pixel defining layer PDL may include an organic material. In some embodiments of the present invention, the pixel defining layer PDL may include at least one of, for example, acrylic resin, epoxy resin, phenolic resin, polyamide resin, and/or polyimide resin. However, the present invention is not limited thereto. In some embodiments of the present invention, the pixel defining layer PDL may include an inorganic material.

The first protective layer PVX1 may be disposed on the second electrode ELT2 and the pixel defining layer PDL. For example, the first protective layer PVX1 may entirely cover the second electrode ELT2. For example, the first protective layer PVX1 may entirely cover the pixel defining layer PDL.

The first protective layer PVX1 may include an inorganic material. The inorganic material may include at least one of, for example, silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and/or silicon oxynitride (SiOₓN_{y}). However, the present invention is not limited thereto. The first protective layer PVX1 may include an organic material.

The planarization layer OML may be disposed on the first protective layer PVX1. For example, the planarization layer OML may entirely cover the first protective layer PVX1. The planarization layer OML may include an organic material. However, the present invention is not limited thereto. The planarization layer OML may include an inorganic material. The planarization layer OML may planarize an upper portion of the light emitting element LD.

The second protective layer PVX2 may be disposed on the planarization layer OML. For example, the second protective layer PVX2 may entirely cover the planarization layer OML. The second protective layer PVX2 may include an inorganic material. However, the present invention is not limited thereto. The second protective layer PVX2 may include an organic material. As organic and inorganic materials are alternately stacked on each other, the light emitting element layer LDL may include a structure capable of encapsulating the light emitting element LD.

The reflective structure layer LAL may be disposed on the second protective layer PVX2. The reflective structure layer LAL may include a first intermediate layer OL1, a second intermediate layer OL2, a third intermediate layer OL3, a third protective layer PVX3, a first reflective layer RL1, and a second reflective layer RL2.

The first intermediate layer OL1 may be disposed on the second protective layer PVX2. The first intermediate layer OL1 may be patterned on the second protective layer PVX2, not to overlap with at least a portion of the second protective layer PVX2. At least a portion of the first intermediate layer OL1 may overlap with at least a portion of the second protective layer PVX2.

At least a portion of the first intermediate layer OL1 may have an opening exposing at least a portion of the second protective layer PVX2. An opening area of the first intermediate layer OL1 may overlap with an opening H area of the first reflective layer RL1 in a plan view.

The first intermediate layer OL1 may form (or include) a curved surface. A surface of the first intermediate layer OL1 may be a curved surface. For example, the first intermediate layer OL1 may have a curved surface having the shape of a half of a semicircle or a shape of a section of an ellipse. A curvature (bending degree) of the first intermediate layer OL1 may determine a curvature of the first reflective layer RL1.

The first intermediate layer OL1 may include a surface inclined with respect to a top surface of the second protective layer PVX2 that faces the first intermediate layer OL1. The first intermediate layer OL1 may include a convex surface protruding in a gravity direction (e.g., a lower direction facing the base layer BSL from the reflective structure layer LAL). One surface of the first intermediate layer OL1 may face the second protective layer PVX2.

At least a portion of the first intermediate layer OL1 might not overlap with the light emitting layer EL in a plan view. The first intermediate layer OL1 may have different thicknesses in an area in which the first intermediate layer OL1 does not overlap with the light emitting layer EL and an area in which the first intermediate layer OL1 overlaps with the light emitting layer EL. For example, as the first intermediate layer OL1 approaches the light emitting layer EL, the thickness of the first intermediate layer OL1 decreases.

The first intermediate layer OL1 may include an organic material. However, the present invention is not limited thereto. The first intermediate layer OL1 may include an inorganic material.

The first reflective layer RL1 may be disposed on the first intermediate layer OL1. At least a portion of the first reflective layer RL1 may be patterned to have an opening H exposing at least a portion of the second protective layer PVX2. The opening H may overlap with the light emitting layer EL in a plan view. The first reflective layer RL1 may form (or include) a first curved surface CS1. One surface of the first reflective layer RL1 may be the first curved surface CS1. The first reflective layer RL1 may include a curved surface having the shape of a half of a semicircle or a shape of a portion of an ellipse.

The first reflective layer RL1 may include a surface inclined with respect to a surface of the second protective layer PVX2. The first reflective layer RL1 may include a convex surface protruding in the gravity direction. The convex surface of the first reflective layer RL1 may face the light emitting element layer LDL. The first reflective layer RL1 may have a shape corresponding to the shape of an outer surface of the first intermediate layer OL1. The one surface of the first reflective layer RL1 may be in contact with the one surface of the first intermediate layer OL1.

The first reflective layer RL1 may include a material capable of reflecting light. For example, the first reflective layer RL1 may include at least one of, for example, lithium (Li), calcium (Ca), lithium fluoride/calcium ((LiₓF_{y})/Ca), lithium fluoride/aluminum ((LiₓF_{y})/Al), aluminum (Al), silver (Ag), magnesium (Mg), gold (Au), titanium oxide (TixOy), and/or silicon oxide (SixOy). In some embodiments of the present invention, the first reflective layer RL1 may have a single-layer structure including aluminum (Al) or magnesium (Mg), and have a multi-layer structure in which titanium oxide (TixOy) and silicon oxide (SixOy) are sequentially stacked.

The second intermediate layer OL2 may be disposed on the first reflective layer RL1. For example, the second intermediate layer OL2 may entirely cover the first reflective layer RL1. At least a portion of the second intermediate layer OL2 may be disposed on the second protective layer PVX2. For example, at least a portion of the second intermediate layer OL2 may be in contact with the second protective layer PVX2. For example, at least a portion of the second intermediate layer OL2 may be in contact with at least a portion of the first reflective layer RL1.

The second intermediate layer OL2 may form (or include) a curved surface. Each of one surface and the other surface of the second intermediate layer OL2 may be a curved surface. For example, the second intermediate layer OL2 may include a curved surface having the shape of a half of a semicircle or a shape of a portion of an ellipse. A curvature (e.g., a bending degree) of the second intermediate layer OL2 may determine a curvature of the second reflective layer RL2.

The second intermediate layer OL2 may include a surface inclined with respect to the top surface of the second protective layer PVX2 facing the second intermediate layer OL2. The second intermediate layer OL2 may include a convex surface protruding in the gravity direction (e.g., the lower direction facing the base layer BSL from the reflective structure layer LAL). One surface of the second intermediate layer OL2 may face the second protective layer PVX2.

The second intermediate layer OL2 may include an organic material. However, the present invention is not limited thereto, and the second intermediate layer OL2 may include an inorganic material.

The second reflective layer RL2 may be disposed on the second intermediate layer OL2. The second reflective layer RL2 may be spaced apart from the first reflective layer RL1 with the second intermediate layer OL2 interposed therebetween. One surface of the second reflective layer RL2 may be in contact with the other surface of the second intermediate layer OL2.

The second reflective layer RL2 may form (or include) a second curved surface CS2. The second reflective layer RL2 may include a curved surface having the shape of a half of a semicircle or a shape of a portion of an ellipse. The second reflective layer RL2 may include a convex surface protruding in the gravity direction. The convex surface of the second reflective layer RL2 may face the light emitting element layer LDL. The second reflective layer RL2 may have a shape corresponding to the shape of an outer surface of the second intermediate layer OL2.

The second reflective layer RL2 might not include any opening. For example, the second reflective layer RL2 might not include any opening at a position corresponding to the opening H of the first reflective layer RL1. For example, the second reflective layer RL2 may entirely overlap with the light emitting layer EL in a plan view. In a plan view, an area in which the second reflective layer RL2 can be disposed may entirely overlap with an area in which the light emitting layer EL can be disposed.

The second curved surface CS2 of the second reflective layer RL2 and the first curved surface CS1 of the first reflective layer RL1 may be spaced apart from each other. The second curved surface CS2 of the second reflective layer RL2 and the first curved surface CS1 of the first reflective layer RL1 may face each other. The second curved surface CS2 of the second reflective layer RL2 and the first curved surface CS1 of the first reflective layer RL1 may be spaced apart from each other in a thickness direction of the base layer BSL. The second intermediate layer OL2 may be disposed between the second curved surface CS2 of the second reflective layer RL2 and the first curved surface CS1 of the first reflective layer RL1. The second reflective layer RL2 and the first reflective layer RL1 may have a Cassegrain type arrangement form. For example, the second curved surface CS2 of the second reflective layer RL2 may be a hyperboloid, and the first curved surface CS1 of the first reflective layer RL1 may be a paraboloid. For example, the first curved surface CS1 of the first reflective layer RL1 may be a paraboloid including (or forming) the opening H.

The second curved surface CS2 of the second reflective layer RL2 and the first curved surface CS1 of the first reflective layer RL1 may be bent in the same direction as each other. The second curved surface CS2 of the second reflective layer RL2 and the first curved surface CS1 of the first reflective layer RL1 may be convex surfaces protruding in the same direction as each other. The second curved surface CS2 of the second reflective layer RL2 and the first curved surface CS1 of the first reflective layer RL1 may be convex surfaces protruding in the gravity direction. The second curved surface CS2 of the second reflective layer RL2 and the first curved surface CS1 of the first reflective layer RL1 may have a convex shape protruding in a direction in which the light emitting element LD is disposed.

In some embodiments of the present invention, the second reflective layer RL2 and the first reflective layer RL1 may have the same curvature radius as each other. However, the present invention is not limited thereto, and the second reflective layer RL2 and the first reflective layer RL1 may have different curvature radii.

The second reflective layer RL2 may include a material capable of reflecting light. For example, the second reflective layer RL2 may include at least one of, for example, lithium (Li), calcium (Ca), lithium fluoride/calcium ((LiₓF_{y})/Ca), lithium fluoride/aluminum ((LiₓF_{y})/Al), aluminum (Al), silver (Ag), magnesium (Mg), gold (Au), titanium oxide (TixOy), and/or silicon oxide (SixOy). In some embodiments of the present invention, the second reflective layer RL2 may have a single-layer structure including aluminum (Al) or magnesium (Mg), or have a multi-layer structure in which titanium oxide (TixOy) and silicon oxide (SixOy) are sequentially stacked on each other.

The third intermediate layer OL3 may be disposed on the second reflective layer RL2. One surface of the third intermediate layer OL3 may overlap with the other surface of the second reflective layer RL2. The third intermediate layer OL3 may have a curved surface. The one surface of the third intermediate layer OL3 may be a curved surface. For example, the third intermediate layer OL3 may include a curved surface having the shape of a half of a semicircle or a shape of a portion of an ellipse. As another example, the third intermediate layer OL3 may have a substantially flat surface and a curved surface.

The third intermediate layer OL3 may include an organic material. However, the present invention is not limited thereto, and the third intermediate layer OL3 may include an inorganic material.

The third protective layer PVX3 may be disposed on the third intermediate layer OL3. For example, the third protective layer PVX3 may entirely cover the third intermediate layer OL3.

The third protective layer PVX3 may include an inorganic material. However, the present invention is not limited thereto, and the third protective layer PVX3 may include an organic material.

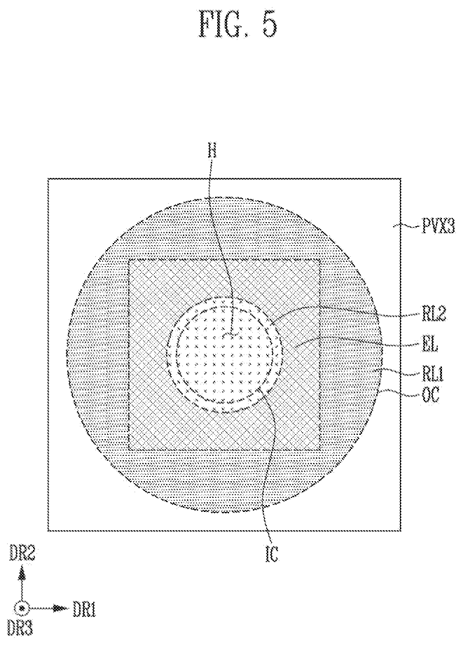

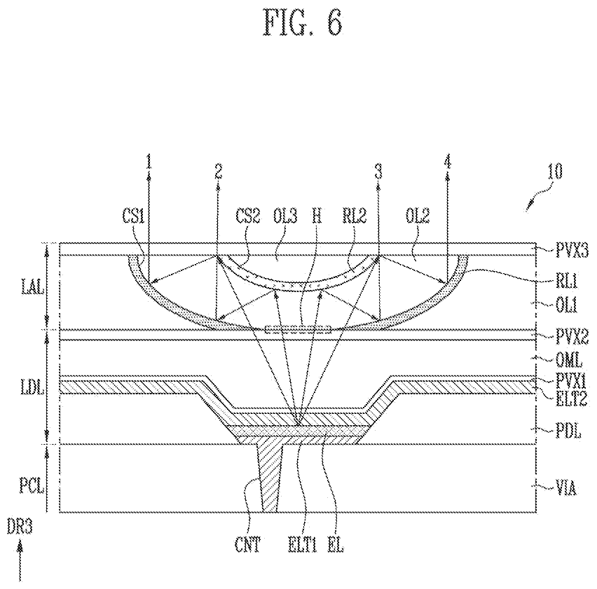

FIG. 5 is a schematic plan view of the display device shown in FIG. 4 in accordance with an embodiment of the present invention. FIG. 5 may be a schematic plan view of the display device 10 shown in FIG. 4, which is viewed from the top in the thickness direction of the base layer BSL (e.g., a third direction DR3).

Hereinafter, an arrangement of the first reflective layer RL1 and the second reflective layer RL2 will be described in more detail with reference to FIG. 5.

The first reflective layer RL1 may be patterned to expose at least a partial area of a lower portion thereof, thereby including the opening H. The opening H may expose at least a portion of the second protective layer PVX2. The first reflective layer RL1 may have a structure disposed between a first circle OC and a second circle IC. For example, the first reflective layer RL1 may have an annular shape including the opening in a partial area in a plan view.

The first reflective layer RL1 may overlap with at least a portion of the light emitting layer EL in a plan view.

The second reflective layer RL2 may overlap with the light emitting layer EL. The area in which the second reflective layer RL2 is disposed may overlap with the area in which the light emitting layer EL is disposed.

The area in which the second reflective layer RL2 is disposed may overlap with an area of the second circle IC, in which the first reflective layer RL1 is not disposed. In this drawing, it is illustrated that the area in which the second reflective layer RL2 is disposed is wider than the area of the second circle IC, in which the first reflective layer RL1 is not disposed. However, the present invention is not limited thereto. In some embodiments of the present invention, in this drawing, the area in which the second reflective layer RL2 is disposed is narrower than the area of the second circle IC, in which the first reflective layer RL1 is not disposed.

The area in which the second reflective layer RL2 is disposed, the opening H, and the area in which the light emitting layer EL is disposed may overlap with each other.

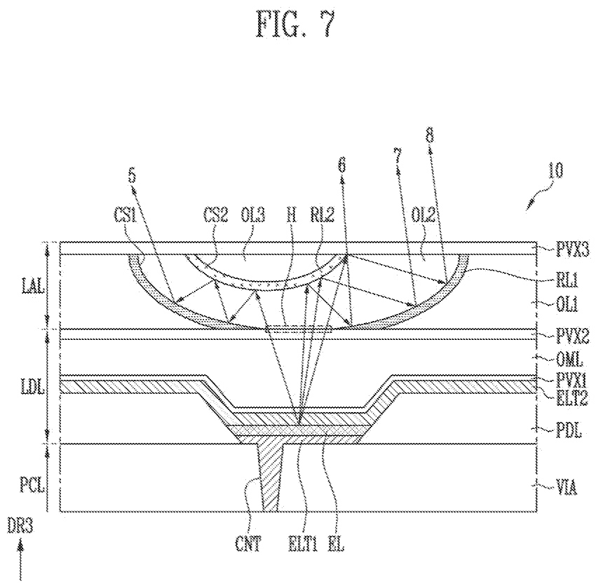

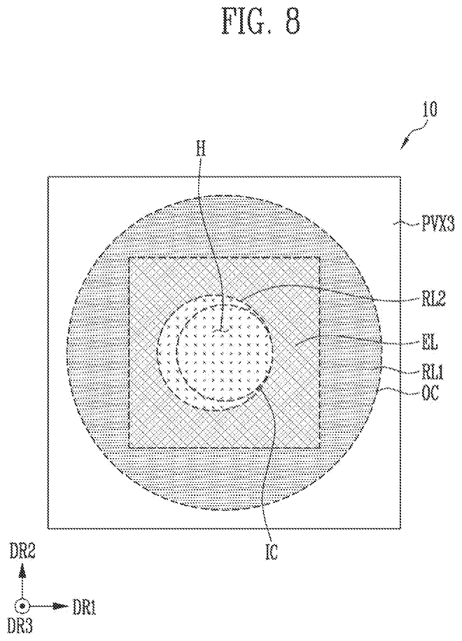

FIGS. 6 and 7 are schematic views illustrating emission directions of light, which is determined by a reflective structure layer in accordance with an embodiment of the present invention. FIGS. 6 and 7 respectively illustrate different structures according to arrangement structures of the first reflective layer RL1 and the second reflective layer RL2. FIG. 8 is a plan view of a display device shown in FIG. 7. For example, FIGS. 7 and 8 may be views illustrating a reflective structure layer LAL in accordance with an embodiment of the present invention.

Referring to FIG. 6 in conjunction with FIG. 5, in a display device 10 in accordance with an embodiment of the present invention, the center of the second reflective layer RL2 and the center of the first reflective layer RL1 may correspond to each other in a plan view.

For example, the center of the second reflective layer RL2 and the center of the light emitting layer EL may correspond to each other. For example, the center of the second reflective layer RL2 and the center of the light emitting layer EL may be aligned with each other. For example, the center of the second reflective layer RL2 and the center of the first reflective layer RL1 may overlap with each other at the substantially same position in a plan view. For example, the center of the second reflective layer RL2 and the center of the light emitting layer EL may overlap with each other at the substantially same position in a plan view.

At least a portion of light emitted from the light emitting layer EL may be emitted along first to fourth emission directions 1 to 4.

In this drawing, for convenience, only the first to fourth emission directions 1 to 4 are illustrated as emission directions. However, the present invention is not limited thereto. The light emitted from the light emitting layer EL may include various emission directions.

The light emitted from the light emitting layer EL may pass through the second electrode ELT2, the first protective layer PVX1, the planarization layer OML, and the second protective layer PVX2. The light emitted from the light emitting layer EL may pass through the second protective layer PVX2 and then pass through the opening H of the first reflective layer RL1.

At least one of the emitted lights passing through the opening H of the first reflective layer RL1 may pass through the second intermediate layer OL2. At least one of the emitted lights passing through the second intermediate layer OL2 may be reflected from the second reflective layer RL2. At least a portion of the light reflected from the second reflective layer RL2 may pass through the second intermediate layer OL2, and be reflected from the first reflective layer RL1. The light reflected from the first reflective layer RL1 may pass through the second intermediate layer OL2, and pass through the third protective layer PVX3. Therefore, at least a portion of the light emitted from the light emitting layer EL may be emitted along the first to fourth emission directions 1 to 4, to be emitted to the outside of the display device 10.

The display device 10 in accordance with an embodiment of the present invention may include the first reflective layer RL1 having the first curved surface CS1 and the second reflective layer RL2 including the second curved surface CS2, which is bent in the same direction as the first curved surface CS1, above the first reflective layer RL1, and allow light emitted from the light emitting layer EL to be reflected from the second reflective layer RL2 and the first reflective layer RL1. Accordingly, the light emitted from the light emitting layer EL can be emitted to an area not overlapping with the light emitting layer EL through reflection.

Conventionally, light emitted from the light emitting layer EL might be emitted in only the area in which the light emitting layer EL is disposed. Therefore, it might be difficult for the display device 10 to have a relatively high light emission efficiency. To reduce this, in some conventional light emitting devices, a component such as a lens for refracting light was disposed on the light emitting element layer LDL, thereby refracting light emitted from the display device 10, so that the emission range of light could be adjusted. The component for refracting light may be, for example, a micro lens array. Conventionally, the micro lens array might be disposed on the light emitting element layer LDL.

A micro lens may be formed through an injection molding process or an etching process. When the micro lens is manufactured through the injection molding process, the first intermediate layer OL1 may be deposited on the second protective layer PVX2, and a mask for injection molding may be disposed on the first intermediate layer OL1. The mask for injection molding may be manufactured with a large area to cover the whole of the first intermediate layer OL1. However, it was difficult for the mask for injection molding to be manufactured with a large area, and it was difficult to accurately manufacture the mask for injection molding to have the shape of a lens. In addition, it was difficult to accurately align the mask for injection molding on the first intermediate layer OL1. In addition, a portion of the first intermediate layer OL1 might be injection-molded together with the mask for injection molding when the mask for injection molding is injection-molded, and a risk might exist that the micro lens was damaged as the first intermediate layer OL1 was injection-molded together with the mask for injection molding.

When the micro lens is manufactured through the etching process, the first intermediate layer OL1 may be deposited and then etched, to form a concave surface or a convex surface. The first intermediate layer OL1 is to form a complete spherical surface to refract light. This uses a high degree of etching precision. Hence, it may be difficult to form a spherical surface by etching the first intermediate layer OL1.

The display device 10 in accordance with an embodiment of the present invention may include the first reflective layer RL1 and the second reflective layer RL2 on the first intermediate layer OL1, and the arrangement of the first reflective layer RL1 and the second reflective layer RL2 may be adjusted, so that the reflection and emission range of light can be adjusted. The display device 10 in accordance with an embodiment of the present includes the first reflective layer RL1 and the second reflective layer RL2, so that the necessity that light should be refracted using the first intermediate layer OL1 can be relatively decreased. In addition, the necessity that the display device 10 should be manufactured such that the first intermediate layer OL1 forms a complete spherical surface can be decreased.

Referring to FIG. 7 in conjunction with FIG. 8, in a display device 10 in accordance with an embodiment of the present invention, the center of the second reflective layer RL2 and the center of the first reflective layer RL1 might not correspond to each other in a plan view.

For example, the center of the second reflective layer RL2 and the center of the light emitting layer EL might not correspond to each other. For example, the center of the second reflective layer RL2 and the center of the light emitting layer EL might not be aligned with each other. The center of the second reflective layer RL2 and the center of the first reflective layer RL1 may have positions substantially different from each other in a plan view. The center of the second reflective layer RL2 and the center of the light emitting layer EL may have positions substantially different from each other in a plan view.

At least a portion of light emitted from the light emitting layer EL may be emitted along fifth to eighth emission directions 5 to 8. The fifth to eighth emission directions 5 to 8 may each include a direction inclined with respect to a surface of the display device 10. For example, the fifth to eighth emission directions 5 to 8 may each include a direction inclined with respect to a surface of the base layer BSL.

In this drawing, only the fifth to eighth emission directions 5 to 8 are illustrated as emission directions. However, the present invention is not limited thereto. The light emitted from the light emitting layer EL may include various emission directions.

The light emitted from the light emitting layer EL may pass through the second electrode ELT2, the first protective layer PVX1, the planarization layer OML, and the second protective layer PVX2. The light emitted from the light emitting layer EL may pass through the second protective layer PVX2 and then pass through the opening H of the first reflective layer RL1.

The light passing through the opening H of the first reflective layer RL1 may pass through the second intermediate layer OL2. The light passing through the second intermediate layer OL2 may be reflected from the second reflective layer RL2. The light reflected from the second reflective layer RL2 may pass the second intermediate layer OL2, and be reflected from the first reflective layer RL1. The light reflected from the first reflective layer RL1 may pass through the second intermediate layer OL2, and pass through the third protective layer PVX3. Therefore, at least a portion of the light emitted from the light emitting layer EL may be emitted along the fifth to eighth emission directions 5 to 8, to be emitted to the outside of the display device 10.

In the display device 10 shown in FIG. 6 and the display device 10 shown in FIG. 7, the second reflective layer RL2 is differently disposed, so that the reflection and emission direction of the light emitted from the light emitting layer EL can be adjusted. In the display device 10 in accordance an embodiment of the present invention, light emitted from the light emitting layer EL may be emitted to an area not overlapping with the light emitting layer EL. For example, conventionally, light, which could be emitted by the area of the light emitting layer EL, could be emitted by the area of the first reflective layer RL1. Hence, in the display device 10 in accordance with an embodiment of the present invention, light extraction efficiency can be increased, and the range of the light emitting layer EL viewed by a user can be enlarged.

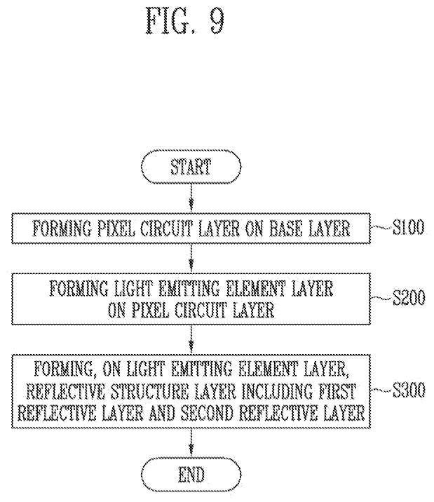

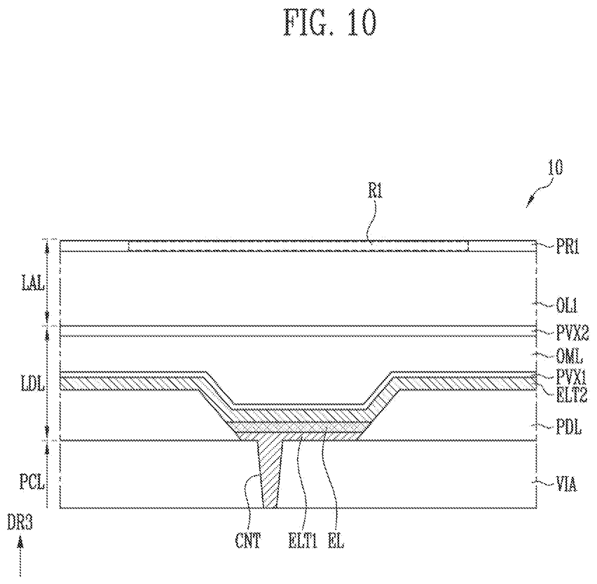

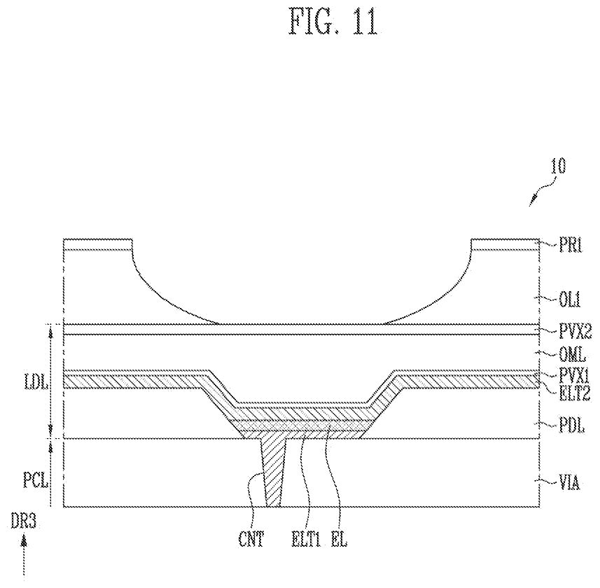

FIG. 9 is a flowchart illustrating a method of manufacturing a display device in accordance with an embodiment of the present invention. FIGS. 10 to 16 are process sectional views of the display device illustrating various steps of the method of manufacturing the display device. Hereinafter, a method of manufacturing a display device 10 in accordance with an embodiment of the present invention will be described with reference to FIGS. 9 to 16. In FIGS. 9 to 16, descriptions of portions overlapping with those described above will be simplified or omitted to prevent redundant descriptions.

Referring to FIG. 9, the method of manufacturing the display device 10 may include step S100 of forming a pixel circuit layer on a base layer, step S200 of forming a light emitting element layer on the pixel circuit layer, and step S300 of forming, on the light emitting element layer, a reflective structure layer including a first reflective layer and a second reflective layer.

In the step S100 of forming the pixel circuit layer on the base layer, a pixel circuit layer PCL including a pixel circuit that includes transistors and capacitors may be formed on a base layer BSL.

In this step, the base layer BSL may be prepared, and conductive layers and insulating layers, which are used to form the pixel circuit layer PCL, may be patterned on the base layer BSL. The conductive layers and the insulating layers on the base layer BSL may be formed through an ordinary patterning process (e.g., a photolithography process or the like) by using a mask.

In the disclosure, the patterning process may include a deposition process and an etching process. The deposition process may include, for example, a Physical Vapor Deposition (PVD) process (e.g., a sputtering process or the like), a Chemical Vapor Deposition (CVD) process, an Atomic Layer Deposition (ALD) process, and the like. The etching process may include, for example, wet etching, dry etching, and the like. However, the present invention is not limited to a specific example.

In some embodiments of the present invention, the pixel circuit layer PCL may include a via layer VIA at an uppermost portion thereof, but the present invention is not limited thereto. The via layer VIA may be omitted in some embodiments of the present invention.

The pixel circuit layer PCL may include a contact part CNT formed in an area adjacent to a light emitting element layer LDL. Lines (e.g., the pixel circuit) formed in the pixel circuit layer PCL may be electrically connected to the light emitting element LD through the contact part CNT.

The step S200 of forming the light emitting element layer on the pixel circuit layer may include a step of forming a pixel defining layer PDL and the light emitting element LD on the pixel circuit layer PCL, a step of forming a first protective layer PVX1 on the light emitting element LD, a step of forming a planarization layer OML on the first protective layer PVX1, and a step of forming a second protective layer PVX2 on the planarization layer OML.

First, the pixel defining layer PDL may be patterned on the pixel circuit layer PCL. The pixel defining layer PDL may be selectively patterned in a partial area to define an area in which a first electrode ELT1 and a light emitting layer EL are disposed.

Next, the first electrode ELT1, the light emitting layer EL, and the second electrode ELT2 may be sequentially patterned. For example, the first electrode ELT1 and the light emitting layer EL may be patterned in an area defined by the pixel defining layer PDL, and the second electrode ELT2 may be deposited on the entire surface in a display area DA. For example, the first electrode ELT1, the light emitting layer EL, and the second electrode ELT2 may be disposed in an opening of the pixel defining layer PDL.

The first protective layer PVX1 may be disposed on the light emitting element LD and the pixel defining layer PDL. In some embodiments of the present invention, the first protective layer PVX1 may be deposited on the light emitting element LD, and may entirely cover the second electrode ELT2 of the light emitting element LD.

The planarization layer OML may be disposed on the first protective layer PVX1. In some embodiments of the present invention, the planarization layer OML may be deposited on the first protective layer PVX1, and may entirely cover the first protective layer PVX1.

The second protective layer PVX2 may be disposed on the planarization layer OML. In some embodiments of the present invention, the second protective layer PVX2 may be deposited on the planarization layer OML, and may entirely cover the planarization layer OML.

The step S300 of forming, on the light emitting layer, the reflective structure layer including the first reflective layer and the second reflective layer may include a step of forming a first intermediate layer OL1 on the light emitting element layer LDL, a step of forming a first reflective layer RL1 on the first intermediate layer OL1, a step of forming a second intermediate layer OL2 on the firsts reflective layer RL1, a step of forming a second reflective layer RL2 on the second intermediate layer OL2, a step of forming a third intermediate layer OL3 on the second reflective layer RL2, and a step of forming a third protective layer PVX3 on the third intermediate layer OL3.

First, the first intermediate layer OL1 may be patterned on the second protective layer PVX2.

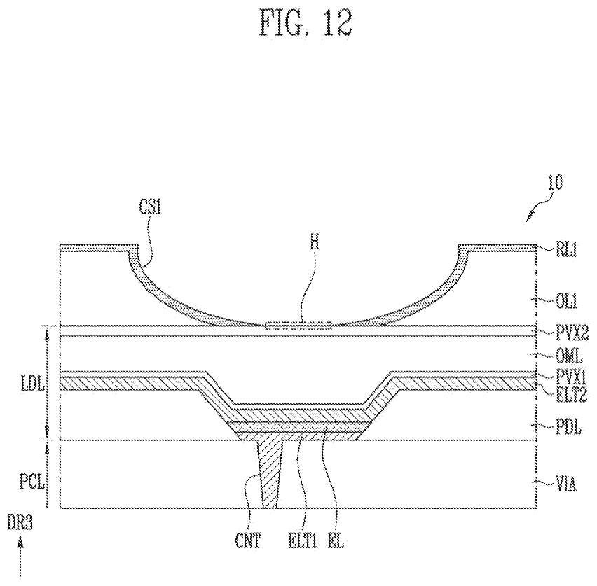

Referring to FIGS. 10 and 11, the first intermediate layer OL1 may be deposited on the second protective layer PVX2, and may entirely cover the second protective layer PVX2. In some embodiments of the present invention, the first intermediate layer OL1 may be deposited on the second protective layer PVX2, and be in contact with the second protective layer PVX2.

After the first intermediate layer OL1 is deposited, a first photoresist PR1 may be entirely disposed (or applied) on the first intermediate layer OL1. The area in which the first photoresist layer PR1 is disposed may include a first mask area R1. The first mask area R1 may have an elliptical or circular shape when viewed from the top of the display device 10. The first mask area R1 may correspond to a position at which a curved surface area of the first reflective layer RL1 is to be formed.

When the first photoresist PR1 is a positive photoresist, a portion of the first photoresist PR1 in the first mask area R1 may be exposed by light to be removed. When the first mask area R1 is exposed by light, the first intermediate layer OL1 may be etched using, as an etching mask, the first photoresist PR1 in an area except the first mask area R1.

When the first photoresist PR1 is a negative photoresist, a portion of the first photoresist PR1 in an area, except the first mask area R1, may be exposed by light to be removed. After the area, except the first mask area R1, is exposed by light, the first intermediate layer OL1 may be etched using, as an etching mask, the first photoresist PR1 in the area, except the first mask area R1.

As the first intermediate layer OL1 is etched, an opening of the first intermediate layer OL1 overlapping with at least a portion of the light emitting layer EL may be formed. The first intermediate layer OL1 may include an opening having a circular or elliptical shape. The first intermediate layer OL1 may form an opening exposing at least a portion of the second protective layer PVX2.

The first intermediate layer OL1 may form (or include) a curved surface. The first intermediate layer OL1 may include a surface inclined with respect to a surface of the second protective layer PVX2. The first intermediate layer OL1 may include a convex surface protruding in a gravity direction. The first intermediate layer OL1 may have different thicknesses in an area not overlapping with the light emitting layer EL and an area overlapping with the light emitting layer EL. For example, as a center of the opening of the first intermediate layer OL1 is approached, the thickness of the first intermediate layer OL1 may decrease. For example, side surfaces of the opening of the first intermediate layer OL1 may be curved.

The first photoresist PR1 not overlapping with the first mask area R1 may be removed (e.g., photoresist strip) after the first intermediate layer OL1 is etched.

Referring to FIG. 12, in the step of forming the first reflective layer RL1 on the first intermediate layer OL1, the first reflective layer RL1 may be disposed on the first intermediate layer OL1.

The first reflective layer RL1 may be deposited on an entirety of the first intermediate layer OL1, and be in contact with at least a portion of the second protective layer PVX2 through the opening formed in the first intermediate layer OL1.

The first reflective layer RL1 may be deposited on the first intermediate layer OL1 to form (or include) a first curved surface CS1. For example, the first reflective layer RL1 may be conformally formed on the first intermediate layer OL1. The first reflective layer RL1 may include a surface inclined with respect to a top surface of the second protective layer PVX2. The first reflective layer RL1 may include a convex surface protruding in the gravity direction.

The first reflective layer RL1 may be deposited with a material capable of reflecting light. In some embodiments of the present invention, the first reflective layer RL1 may be deposited as a single layer including aluminum (Al) or magnesium (Mg), or be deposited as a multi-layer in which titanium oxide (TixOy) and silicon oxide (SixOy) are sequentially stacked on each other.

At least a portion of the first reflective layer RL1 may be etched. The first reflective layer RL1 may form an opening H capable of overlapping with at least a portion of the light emitting layer EL. In some embodiments of the present invention, the first reflective layer RL1 may form the opening H smaller than an area in which the light emitting element EL can be disposed.

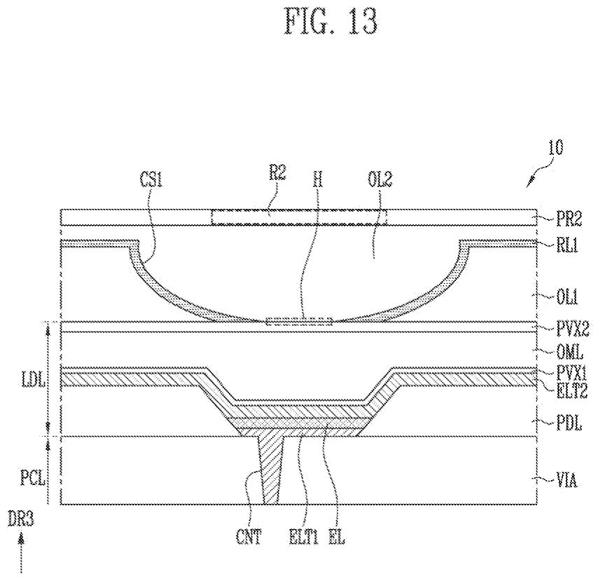

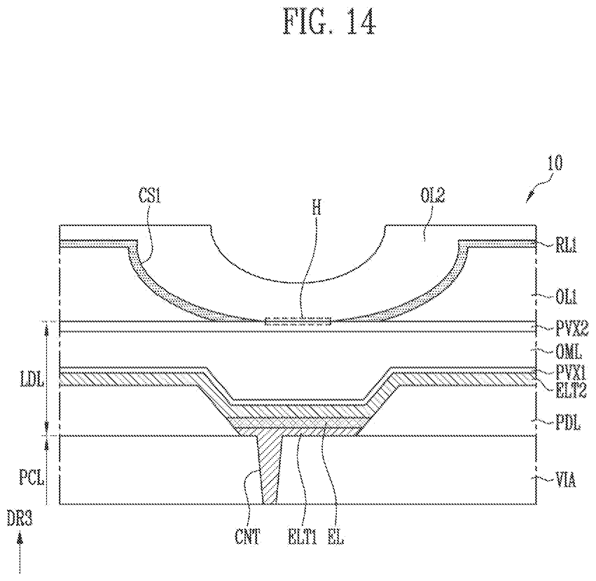

Referring to FIGS. 13 and 14, the second intermediate layer OL2 may be disposed on the first reflective layer RL1.

The second intermediate layer OL2 may be deposited on an entirety the first reflective layer RL1. The second intermediate layer OL2 may entirely cover the first reflective layer RL1. At least a portion of one surface of the second intermediate layer OL2 may be in contact with the second protective layer PVX2. At least a portion of the second intermediate layer OL2 may be deposited on the opening H. The second intermediate layer OL2 may be deposited on the first reflective layer RL1, and at least a portion of the one surface of the second intermediate layer OL2 may be in contact with the other surface of the first reflective layer RL1. When the second intermediate layer OL2 is deposited, the other surface of the second intermediate layer OL2 may be substantially flat.

After the second intermediate layer OL2 is deposited, a second photoresist PR2 may be disposed (or applied) on the second intermediate layer OL2. The area in which the second photoresist PR2 is disposed may include a second mask area R2. The second mask area R2 may have an elliptical or circular shape when viewed from the top.

When the second photoresist PR2 is a positive photoresist, a portion of the second photoresist PR2 in the second mask area R2 may be exposed by light to be removed. After the second mask area R2 is exposed by light, the second intermediate layer OL2 may be etched using, as an etching mask, the second photoresist PR2 in an area except the second mask area R2.

When the second photoresist PR2 is a negative photoresist, a portion of the second photoresist PR2 in an area, except the second mask area R2, may be exposed by light to be removed. When the area, except the second mask area R2, is exposed by light, the second intermediate layer OL2 may be etched using, as an etching mask, the second photoresist PR2 in the area, except the second mask area R2.

The second intermediate layer OL2 may form (or include) a curved surface. For example, the second intermediate layer OL2 may include a semicircular opening. For example, the second intermediate layer OL2 may include a surface inclined with respect to the top surface of the second protective layer PVX2. The second intermediate layer OL2 may include a convex surface protruding in the gravity direction.

The second intermediate layer OL2 may form (or include) a curved surface. As the second intermediate layer OL2 is etched, the other surface of the second intermediate layer OL2 may form a curved surface.

The second photoresist PR2 not overlapping with the second mask area R2 may be removed (e.g., photoresist strip) after the second intermediate layer OL2 is etched.

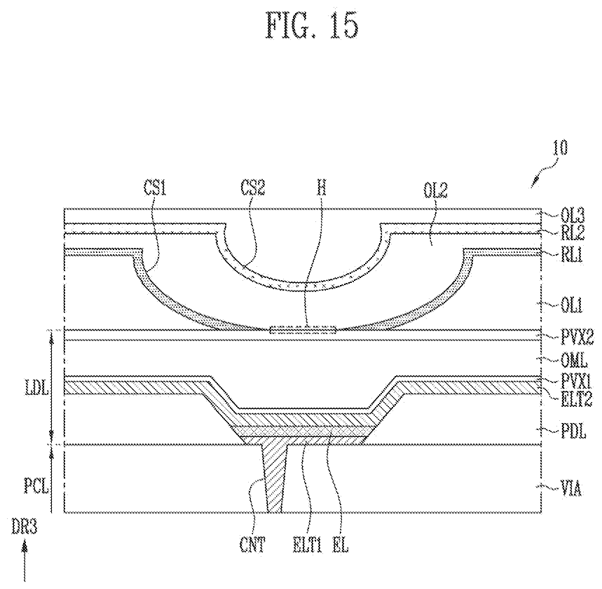

Referring to FIG. 15, the second reflective layer RL2 may be disposed on the second intermediate layer OL2. The second reflective layer RL2 may be deposited on the second intermediate layer OL2. The second reflective layer RL2 may be deposited on an entirety of the second intermediate layer OL2.

The second reflective layer RL2 may be deposited on the second intermediate layer OL2 to form (or include) a second curved surface CS2. The second reflective layer RL2 may include a surface inclined with respect to the surface of the second protective layer PVX2. The second reflective layer RL2 may include a surface protruding in the gravity direction.

The second reflective layer RL2 may be deposited with a material capable of reflecting light. In some embodiments of the present invention, the second reflective layer RL2 may be deposited as a single layer including aluminum (Al) or magnesium (Mg), or be deposited as a multi-layer in which titanium oxide (TixOy) and silicon oxide (SixOy) are sequentially stacked on each other.

In some embodiments of the present invention, a deposition thickness of the second reflective layer RL2 may be substantially equal to a deposited thickness of the first reflective layer RL1. However, the present invention is not limited thereto. Therefore, the second reflective layer RL2 may be deposited to have a thickness different from a thickness of the first reflective layer RL1.

In the step of forming the third intermediate layer OL3 on the second reflective layer RL2, the third intermediate layer OL3 may be patterned on the second reflective layer RL2.

The third intermediate layer OL3 may be entirely deposited on the second reflective layer RL2. For example, the third intermediate layer OL3 may be deposited on an entirety of the second reflective layer RL2.

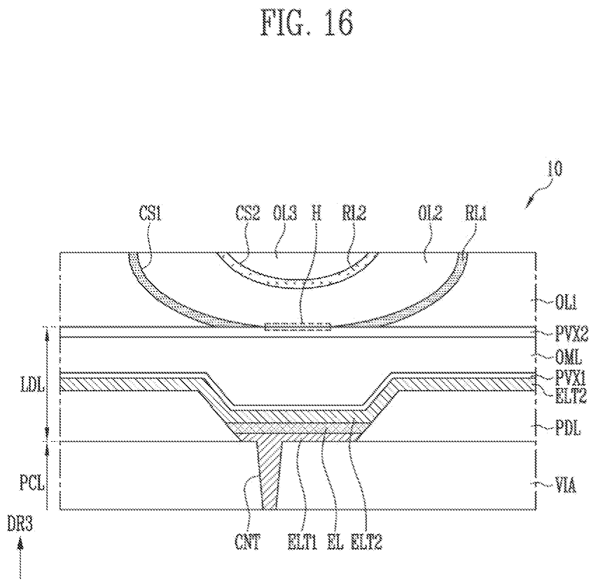

Referring to FIG. 16, after the third intermediate layer OL3 is deposited, at least a portion of each of the third intermediate layer OL3, the second reflective layer RL2, the second intermediate layer OL2, the first reflective layer RL1, and the first intermediate layer OL1 may be etched. For example, as the at least a portion of each of the third intermediate layer OL3, the second reflective layer RL2, the second intermediate layer OL2, the first reflective layer RL1, and the first intermediate layer OL1 is etched, portions of each of the third intermediate layer OL3, the second reflective layer RL2, the second intermediate layer OL2, the first reflective layer RL1, and the first intermediate layer OL1 may be exposed as shown in FIG. 16. For example, a Chemical Mechanical Polishing (CMP) process may be performed such that as the at least a portion of each of the third intermediate layer OL3, the second reflective layer RL2, the second intermediate layer OL2, the first reflective layer RL1, and the first intermediate layer OL1 may be exposed.

Next, in conjunction with FIG. 4, the third protective layer PVX3 may be deposited on third intermediate layer OL3, the second reflective layer RL2, the second intermediate layer OL2, the first reflective layer RL1, and the first intermediate layer OL1. The third protective layer PVX3 may be in contact with at least a portion of each of the third intermediate layer OL3, the second reflective layer RL2, the second intermediate layer OL2, the first reflective layer RL1, and the first intermediate layer OL1. Accordingly, after the third protective layer PVX3 is formed, the stacked structure shown in FIG. 4, which is included in the display device 10 in accordance with an embodiment of the present invention, may be manufactured.

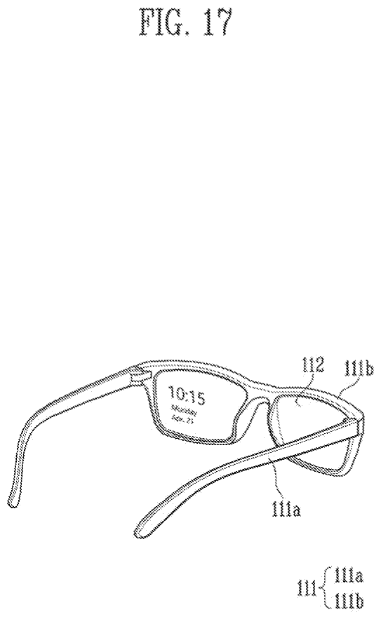

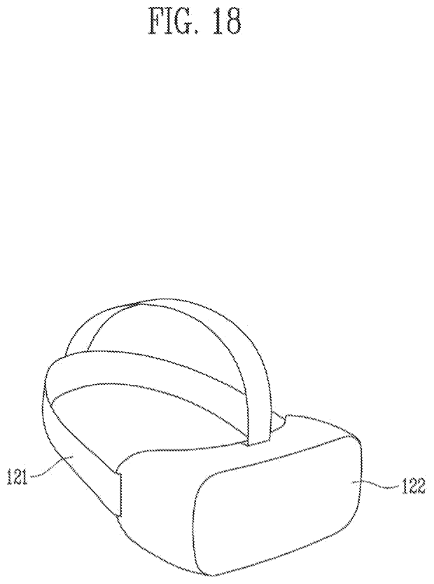

FIGS. 17 and 18 are schematic views illustrating examples of an electronic device including the display device shown in FIG. 1 according to an embodiment of the present invention.

Referring to FIG. 17, the display device in accordance with the above-described embodiments may be applied to smart glasses. The smart glasses may include a frame 111 and a lens part 112. The smart glasses are a wearable electronic device which can be worn on the face of a user, and may have a structure in which a portion of the frame 111 may be folded or unfolded. For example, the smart glasses may be a wearable device for Augmented Reality (AR).

The frame 111 may include a housing 111b, which supports the lens part 112, and a leg part 111a for allowing the user to wear the smart glasses. The leg part 111a may be connected to the housing 111b by a hinge to be folded or unfolded.

A battery, a touch pad, a microphone, and/or a camera may be built in the frame 111. In addition, a projector for outputting light and/or a processor for controlling a light signal may be built in the frame 111.

The lens part 112 may be an optical member which allows light to be transmitted therethrough or allows light to be reflected thereby. The lens part 112 may include glass and/or transparent synthetic resin.

The display device in accordance with the above-described embodiments may be applied to the lens part 112. In an example, the user may recognize an image displayed by a light signal transmitted from the projector of the frame 111 through the lens part 112. For example, the user may recognize information including time, data, and the like, which are displayed on the lens part 112.

Referring to FIG. 18, the display device in accordance with the above-described embodiments may be applied to a Head Mounted Display (HMD). The HMD may include a head mounted band 121 and a display accommodating case 122. For example, the HMD is a wearable electronic device which can be worn on the head of a user.

The head mounted band 121 may be connected to the display accommodating case 122, to fix the display accommodating case 122 to a user. As shown in FIG. 18, the head mounted band 121 may include a horizontal band and a vertical band to fix the HMD to the head of the user. The horizontal band may be provided to at least partially surround a side portion of the head of the user, and the vertical band may be provided to at least partially surround a top portion of the head of the user. However, the present invention is not necessarily limited thereto, and the head mounted band 121 may be implemented in the shape of a frame for a pair of glasses or a helmet.

The display accommodating case 122 accommodates the display device, and may include at least one lens. The at least one lens may provide an image to the user. For example, the display device in accordance with the above-described embodiments may be applied to a left-eye lens and a right-eye lens, which are implemented in the display accommodating case 122.

In accordance with embodiments of the present invention, there can be provided a display device and a method of manufacturing a display device, in which the emission direction of light is controlled, so that light emission efficiency can be increased.

While the present invention has been particularly shown and described with reference to embodiments thereof, it will be apparent those of ordinary skill in the art that various changes in form and detail may be made thereto without departing from spirit and scope of the present invention.

What is claimed is:

1. A display device comprising:
a base layer;
a pixel circuit layer disposed on the base layer, wherein the pixel circuit layer includes a pixel circuit;
a light emitting element layer disposed on the pixel circuit layer, wherein the light emitting element layer includes a light emitting element electrically connected to the pixel circuit; and
a reflective structure layer disposed on the light emitting element layer,
wherein the reflective structure layer includes:
a first intermediate layer disposed on the light emitting element;
a first reflective layer disposed on the first intermediate layer;
a second intermediate layer disposed on the first reflective layer; and
a second reflective layer disposed on the first reflective layer while being spaced apart from the first reflective layer,
wherein the first reflective layer includes a first curved surface, and
wherein the second reflective layer includes a second curved surface which faces the first curved surface and is spaced apart from the first curved surface.

2. The display device of claim 1, wherein the first curved surface and the second curved surface protrude in a direction in which the light emitting element is disposed.

3. The display device of claim 1, wherein the first curved surface and the second curved surface are bent in a same direction as each other.

4. The display device of claim 3, wherein the first curved surface is a paraboloid, and
the second curved surface is a hyperboloid.

5. The display device of claim 4, wherein the first reflective layer and the second reflective layer have a same radius of curvature radius as each other.

6. The display device of claim 4, wherein the first reflective layer and the second reflective layer have a different radius of curvature from each other.

7. The display device of claim 1, wherein the light emitting element includes:
a first electrode;
a light emitting layer disposed on the first electrode; and
a second electrode disposed on the light emitting layer,
wherein the first reflective layer includes an opening,
wherein the second reflective layer does not include an opening, and
wherein the opening of the first reflective layer, the light emitting layer, and the second reflective layer overlap with each other.

8. The display device of claim 7, wherein an area in which the second reflective layer is disposed entirely overlaps with an area in which the light emitting layer is disposed.

9. The display device of claim 8, wherein a center of the first reflective layer and a center of the second reflective layer correspond to each other.

10. The display device of claim 8, wherein a center of the first reflective layer and a center of the second reflective layer are misaligned with each other.

11. The display device of claim 1, wherein the first reflective layer has a single-layer structure, which includes at least one of aluminum (Al) or magnesium (Mg), or a multi-layer structure in which titanium oxide (TixOy) and silicon oxide (SixOy) are stacked on each other, and
the second reflective layer has a single-layer structure, which includes at least one of aluminum (Al) and magnesium (Mg), or a multi-layer structure in which titanium oxide (TixOy) and silicon oxide (SixOy) are stacked on each other.

12. A display device comprising:
a base layer;
a pixel circuit layer disposed on the base layer, wherein the pixel circuit layer includes a pixel circuit;
a light emitting element layer disposed on the pixel circuit layer,
wherein the light emitting element layer includes a light emitting element electrically connected to the pixel circuit; and
a reflective structure layer disposed on the light emitting element layer,
wherein the light emitting element layer includes:
a first electrode;
a light emitting layer disposed on the first electrode; and
a second electrode disposed on the light emitting layer,
wherein the reflective structure layer includes:
a first intermediate layer disposed on the second electrode;
a first reflective layer disposed on the first intermediate layer, wherein the first reflective layer includes an opening;
a second intermediate layer disposed on the first reflective layer; and
a second reflective layer disposed on the second intermediate layer,
wherein the first reflective layer has a first curved surface, and the second reflective layer has a second curved surface, and
wherein an area in which the opening of the first reflective layer is disposed overlaps with an area in which the light emitting layer is disposed.

13. The display device of claim 12, wherein each of the first curved surface and the second curved surface includes a surface inclined with respect to a top surface of the first intermediate layer.

14. The display device of claim 12, wherein the first reflective layer and the second reflective layer have a Cassegrain type arrangement form.

15. The display device of claim 12, wherein the light emitting layer emits light, and
wherein at least a portion of the light passes through the opening,
at least a portion of the light is reflected from the second reflective layer, and
at least a portion of the light is reflected from the first reflective layer.

16. The display device of claim 15, wherein the light is emitted to an area overlapping with the first reflective layer.

17. A method of manufacturing a display device, the method comprising:
patterning a pixel circuit layer on a base layer;
patterning a light emitting element layer on the pixel circuit layer; and
patterning a reflective structure layer on the light emitting element layer,
wherein the patterning of the reflective structure layer on the light emitting element layer includes:
forming a first intermediate layer on the light emitting element layer;
patterning a first reflective layer on the first intermediate layer;
forming a second intermediate layer on the first reflective layer; and
patterning a second reflective layer on the second intermediate layer, and
wherein the first reflective layer includes a first curved surface, and the second reflective layer includes a second curved surface.

18. The method of claim 17, wherein the forming of the first intermediate layer on the light emitting element layer includes:
depositing the first intermediate layer on the light emitting element layer;
applying a first photoresist, which includes a first area, on the first intermediate layer; and
etching the first photoresist, which includes the first area, and a portion of the first intermediate layer that overlaps with the first area, and
wherein the first intermediate layer is etched to form a curved surface.

19. The method of claim 18, wherein the forming of the second intermediate layer on the first reflective layer includes:
depositing the second intermediate layer on the first reflective layer;
applying a second photoresist, which includes a second area, on the second intermediate layer; and
etching the second photoresist, which includes the second area, and a portion of the second intermediate layer that overlaps with the second area, and
wherein the second intermediate layer is etched to form a curved surface.

20. The method of claim 17, wherein the first reflective layer includes at least one of aluminum (Al), magnesium (Mg), titanium oxide (TixOy), or silicon oxide (SixOy), and
the second reflective layer includes at least one of aluminum (Al), magnesium (Mg), titanium oxide (TixOy), or silicon oxide (SixOy).
